(19) United States
(12) Patent Application Publication
(10) Pub. No.: US 2007/0075626 A1
(43) Pub. Date: Apr. 5, 2007

(54) Electronic devices and processes for forming electronic devices

(76) Inventors: Gang Yu, Santa Barbara, CA (US); Charles D. Lang, Goleta, CA (US); Stephen Sorich, Goleta, CA (US); Alberto Goenaga, Goleta, CA (US); Matthew Stainer, Goleta, CA (US); Paul Anthony Sant, Santa Barbara, CA (US); Dennis Damon Walker, Santa Barbara, CA (US); Charles Douglas MacPherson, Santa Barbara, CA (US); Gordana Srdanov, Santa Barbara, CA (US)

Correspondence Address: E I DU PONT DE NEMOURS AND COMPANY;LEGAL PATENT RECORDS CENTER, BARLEY MILL PLAZA 25/1128, 4417 LANCASTER PIKE, WILMINGTON, DE, 19805, US

(21) Appl. No.: 11/446,945

(22) Filed: Jun. 5, 2006

Related U.S. Application Data
(63) Continuation-in-part of application No. 11/025,522, filed on Dec. 29, 2004.

(51) Int. Cl. H05B 33/00

(52) U.S. Cl. 313/500; 313/505

(57) ABSTRACT

An electronic device includes a substrate, a first layer, a first pixel, and a patterned reactive surface-active layer. The first pixel includes a first pixel driving circuit that overlies the substrate and includes a first electronic component. The first electronic component includes a first electrode and a second layer. The first electrode overlies at least a part of the first pixel driving circuit. The patterned reactive surface-active layer has a lower surface energy than the first layer. A process for forming an electronic device includes forming a first pixel driving circuit over a substrate, forming a first electrode of a first electronic component over the substrate, forming a first layer, forming a patterned reactive surface-active layer, and forming a second layer over the first electrode of the first electronic component.

### CROSS REFERENCE TO RELATED APPLICATIONS

This application is a Continuation-in-Part of U.S. Ser. No. 11/025,522, filed Dec. 29, 2004, which is incorporated herein by reference in its entirety.

### BACKGROUND INFORMATION

1. Field of the Disclosure

The invention relates generally to electronic devices and processes for forming electronic devices, and more specifically, to electronic devices having an organic layer that at least partially overlies pixel driving circuitry and processes for forming such electronic devices.

2. Description of the Related Art

Manufacturers are increasingly turning to electronic devices that include organic electronic components, such as organic light emitting diodes (OLEDs). One type of organic electronic component includes an organic active layer located between two electrodes, an anode and a cathode. For display components, application of a potential across the electrodes results in excitation of the organic active layer and, as a result, emission of electromagnetic radiation, such as visible light. For sensor components, absorption of electromagnetic radiation by the organic active layer results in an electrical potential. Generally, organic electronic components are arranged in rows and several rows form a portion of the electronic devices.

However, traditional methods for producing electronic devices having organic electronic components, such as OLEDs, are costly. In part, this cost is derived from slow manufacturing methods, such as ink-jet printing. Typically, ink-jet printing involves placing drops of organic liquid composition in a well structure, component by component along rows, and stepping row by row through an array of component structures. The ink-jet print head moves between components at rates as low as 40 mm/s. As a result, such methods are time consuming, leading to limited throughput of devices.

In addition, such methods use structures to guide the deposition of liquid composition. The structures, such as well structures, generally partially cover underlying electrodes used in the formation of organic electronic components and, in an active matrix OLED device, cover pixel driving circuits associated with the electrode. Electronic components within the pixel driving circuit are typically sensitive to light and electromagnetic radiation and electronic components, such as TFT transistors, degrade over time and with exposure to radiation. However, when the electrode is partially covered by the structure, the useful surface area for deposition of organic layers of an organic electronic component is reduced. In addition, useful surface area is further reduced by thickness variations near walls of the structure. Such thickness variations reduce the effective emitting area in organic electronic devices, such as display devices. As such, a conflict exists between preventing exposure to sensitive electronic components and component performance relating to useful surface area.

Other methods for providing ink containment are also described in the literature. These are based on containment structures, surface tension discontinuities, and combinations of both. In order to be effective, containment structures must be large, comparable to the wet thickness of the deposited materials. Practical containment structures generally have a negative impact on quality when depositing liquid composition to form continuous layers of organic layers. Consequently, all the layers must be printed.

In addition, surface tension discontinuities are obtained when there are either printed or vapor deposited regions of low surface tension materials. These low surface tension materials generally must be applied before printing or coating the first organic active layer in the pixel area. Generally the use of these treatments impacts the quality when coating continuous non-emissive layers, so all the layers must be printed.

An example of a combination of two ink containment techniques is CF₄-plasma treatment of photoresist well structures (pixel wells, channels). Generally, all of the active layers must be printed in the pixel areas.

All these containment methods have the drawback of precluding continuous coating. Continuous coating of one or more layers is desirable as it can result in higher yields and lower equipment cost. There exists, therefore, a need for improved processes for forming electronic devices.

### SUMMARY

An electronic device includes a substrate, a first layer, a first pixel, and a patterned reactive surface-active layer. The first pixel includes a first pixel driving circuit that overlies the substrate and includes a first electronic component. The first electronic component includes a first electrode and a second layer. The first electrode overlies at least a part of the first pixel driving circuit. Within the first pixel, the second layer overlies the first electrode and the first layer, and the second layer includes a central portion and an edge portion. The edge portion of the second layer has a significantly different thickness than the central portion of the second layer and, from a plan view, at least a part of the edge portion of the second layer overlies at least part of the first pixel driving circuit. The patterned reactive surface-active layer has a lower surface energy than the first layer.

A process for forming an electronic device includes forming a first pixel driving circuit over a substrate, forming a first electrode of a first electronic component over the substrate, forming a first layer, forming a patterned reactive surface-active layer, and forming a second layer over the first electrode of the first electronic component. The first electrode overlies at least part of the first pixel driving circuit. The patterned reactive surface-active layer has a lower surface energy than the first layer. The second layer includes a central portion and an edge portion. The edge portion of the second layer has a significantly different thickness than the central portion of the second layer. From a plan view, at least a part of the edge portion of the second layer overlies at least part of the first pixel driving circuit.

The foregoing general description and the following detailed description are-exemplary and explanatory only and are not restrictive of the invention, as defined in the appended claims.

### BRIEF DESCRIPTION OF THE FIGURES

The invention is illustrated by way of example and not limitation in the accompanying figures.

FIGS. 1 and 2 include a plan view illustration and a cross-sectional view illustration, respectively, of an organic layer.

FIG. 3 includes a schematic illustration of an exemplary pixel driving circuit.

FIG. 4 includes a plan view illustration of a process in the forming of an exemplary electronic device including a first electrode and a pixel driving circuit.

FIGS. 5 and 6 include cross-sectional view illustrations of a process in the formation of an exemplary electronic device, as illustrated in FIG. 4.

FIG. 7 includes a cross-sectional view illustration of a process in the formation of an exemplary electronic device in which an organic layer is printed over the first electrode and, at least in part, over the pixel driving circuit.

FIGS. 8 and 9 include cross-sectional view illustrations of a process in the formation of an exemplary electronic device including the organic layer formed over the first electrode and, at least in part, over the pixel driving circuit.

FIG. 10 includes a cross-sectional view illustration of a process in the formation of an exemplary electronic device including a second electrode formed over the organic layer.

FIG. 11 includes a cross-sectional view illustration of a process in the formation of an exemplary electronic device including the organic layer formed over the first electrode and, at least in part, over the pixel driving circuit, with a reactive surface-active composition layer over the pixel driving circuit.

Skilled artisans appreciate that elements in the figures are illustrated for simplicity and clarity and have not necessarily been drawn to scale. For example, the dimensions of some of the elements in the figures may be exaggerated relative to other elements to help to improve understanding of embodiments of the invention.

### DETAILED DESCRIPTION

In a first aspect, an electronic device includes a substrate, a first layer, a first pixel, and a patterned reactive surface-active layer. The first pixel includes a first pixel driving circuit that overlies the substrate and includes a first electronic component. The first electronic component includes a first electrode and a second layer. The first electrode overlies at least a part of the first pixel driving circuit. Within the first pixel, the second layer overlies the first electrode and the first layer, and the second layer includes a central portion and an edge portion. The edge portion of the second layer has a significantly different thickness than the central portion of the second layer and, from a plan view, at least a part of the edge portion of the second layer overlies at least part of the first pixel driving circuit. The patterned reactive surface-active layer has a lower surface energy than the first layer.

In one embodiment of the first aspect, the second layer is selected from a group consisting of an organic active layer, a charge-transport layer, a charge blocking layer, a charge injection layer and combinations thereof.

In another embodiment of the first aspect, the patterned reactive surface-active layer includes a fluorinated material.

In yet another embodiment of the first aspect, the patterned reactive surface-active layer includes a crosslinkable material.

In still another embodiment of the first aspect, the first layer is selected from a group consisting of a charge-transport layer, a charge blocking layer, a charge injection layer, and combinations thereof.

In still yet another embodiment of the first aspect, the electronic device further includes a second electrode. The second layer is a first organic active layer, and the second electrode overlies the first organic active layer. In a specific embodiment, the electronic device is an organic electronic device.

In a further embodiment of the first aspect, the electronic device further includes a second pixel. The second pixel includes a second pixel driving circuit that overlies the substrate and a second electronic component. The second electronic component includes a first electrode and a third layer. The second layer is a first organic active layer having a composition different from the third layer. The first electrode of the second electronic component overlies at least part of the second pixel driving circuit. Within the second pixel, the third layer overlies the first layer and the first electrode of the second electronic component, the third layer includes a central portion and an edge portion, and the edge portion of the third layer has a significantly different thickness than the central portion of the third layer. From a plan view, at least a part of the edge portion of the third layer overlies at least part of the second pixel driving circuit. In a specific embodiment, from a plan view the second layer and the third layer are spaced apart from each other by a barrier region. In a more specific embodiment, the barrier region includes the patterned reactive surface-active layer. In a still more specific embodiment, the barrier region further includes a well structure, and the patterned reactive surface-active layer overlies the well structure.

In a second aspect, a process for forming an electronic device includes forming a first pixel driving circuit over a substrate, forming a first electrode of a first electronic component over the substrate, forming a first layer, forming a patterned reactive surface-active layer, and forming a second layer over the first electrode of the first electronic component. The first electrode overlies at least part of the first pixel driving circuit. The patterned reactive surface-active layer has a lower surface energy than the first layer. The second layer includes a central portion and an edge portion. The edge portion of the second layer has a significantly different thickness than the central portion of the second layer. From a plan view, at least a part of the edge portion of the second layer overlies at least part of the first pixel driving circuit.

In one embodiment of the second aspect, the second layer is selected from a group consisting of an organic active layer, a charge-transport layer, a charge blocking layer, a charge injection layer and combinations thereof.

In another embodiment of the second aspect, the patterned reactive surface-active layer includes a fluorinated material.

In yet another embodiment of the second aspect, the patterned reactive surface-active layer includes a crosslinkable material.

In still another embodiment of the second aspect, the first layer is selected from a group consisting of a charge-transport layer, a charge blocking layer, a charge injection layer, and combinations thereof.

In still yet another embodiment of the second aspect, the second layer is a first organic active layer, and the process further includes forming a second electrode over the first organic active layer. In a specific embodiment, the electronic device is an organic electronic device.

In a further embodiment of the second aspect, forming a first pixel driving circuit includes-forming a second pixel driving circuit over the substrate and forming the first electrode includes forming a first electrode of a second electronic component over the substrate. The first electrode overlies at least part of the second pixel driving circuit. The process further includes forming a third layer over the first electrode of the second electronic component. The second layer is a first organic active layer having a composition different from the third layer. The third layer includes a central portion and an edge portion. The edge portion of the third layer is significantly thicker than the central portion of the third layer. From a plan view, at least a part of the edge portion of the third layer overlies at least part of the second pixel driving circuit. In a specific embodiment, from a plan view the second layer and the third layer are spaced apart from each other by a barrier region. In a more specific embodiment, the barrier region includes the patterned reactive surface-active layer.

Other features and advantages of the invention will be apparent from the following detailed description, and from the claims. The detailed description first addresses Definitions and Clarification of Terms, followed by Layer Formation and Layer Thickness, Electronic Devices and Process of Forming Such Electronic Devices, Alternative Embodiments and Advantages.

1. Definitions and Clarification of Terms

Before addressing details of embodiments described below, some terms are defined or clarified. The terms “array,” “peripheral circuitry,” and “remote circuitry” are intended to mean different areas or components of an electronic device. For example, an array may include pixels, cells, or other structures within an orderly arrangement (usually designated by columns and rows). The pixels, cells, or other structures within the array may be controlled locally by peripheral circuitry, which may lie on the same substrate as the array but outside the array itself. Remote circuitry typically lies away from the peripheral circuitry and can send signals to or receive signals from the array (typically via the peripheral circuitry). The remote circuitry may also perform functions unrelated to the array. The remote circuitry may or may not reside on the substrate having the array.

The term “barrier region” is intended to mean a region within or overlying a substrate, wherein the region serves a principal function of separating an object or region within or overlying the substrate from contacting a different object or different region within or overlying the substrate.

The term “channel region” is intended to mean a region lying between source/drain regions of a field-effect transistor, whose biasing, via a gate electrode of the field-effect transistor, affects the flow of carriers, or lack thereof, between the source/drain regions.

The term “circuit” is intended to mean a collection of electronic components that collectively, when properly connected and supplied with the proper potential(s), performs a function. A TFT pixel driving circuit for an organic electronic component is an example of a circuit.

The term “connected,” with respect to electronic components, circuits, or portions thereof, is intended to mean that two or more electronic components, circuits, or any combination of at least one electronic component and at least one circuit do not have any intervening electronic component lying between them. Parasitic resistance, parasitic capacitance, or both are not considered electronic components for the purposes of this definition. In one embodiment, electronic components are connected when they are electrically shorted to one another and lie at substantially the same voltage. Note that electronic components can be connected together using fiber optic lines to allow optical signals to be transmitted between such electronic components.

The term “contained” when referring to a layer, is intended to mean that the layer does not spread significantly beyond the area where it is deposited. The layer can be contained by surface energy affects or a combination of surface energy affects and physical barrier structures.

The term “coupled” is intended to mean a connection, linking, or association of two or more electronic components, circuits, systems, or any combination of: (1) at least one electronic component, (2) at least one circuit, or (3) at least one system in such a way that a signal (e.g., current, voltage, or optical signal) may be transferred from one to another. Non-limiting examples of “coupled” can include direct connections between electronic component(s), circuit(s) or electronic component(s) with switch(es) (e.g., transistor(s)) connected between them, or the like.

The term “data line” is intended to mean a signal line having a primary function of transmitting one or more signals that comprise information.

The term “driving transistor” is intended to mean a transistor that acts in response to a signal to drive a different portion of an electronic device. In one embodiment, a control electrode (e.g., a gate electrode or a base region) receives a signal that controls a voltage applied to a different electronic component, current flowing between a power supply line and a different electronic component, or a combination thereof.

The term “electronic component” is intended to mean a lowest level unit of a circuit that performs an electrical or electro-radiative (e.g., electro-optic) function. An electronic component may include a transistor, a diode, a resistor, a capacitor, an inductor, a semiconductor laser, an optical switch, or the like. An electronic component does not include parasitic resistance (e.g., resistance of a wire) or parasitic capacitance (e.g., capacitive coupling between two conductors connected to different electronic components where a capacitor between the conductors is unintended or incidental).

The term “electronic device” is intended to mean a collection of circuits, electronic components, or combinations thereof that collectively, when properly connected and supplied with the appropriate potential(s), performs a function. An electronic device may include or be part of a system. An example of an electronic device includes a display, a sensor array, a computer system, avionics, an automobile, a cellular phone, or other consumer or industrial electronic product.

The term “field-effect transistor” is intended to mean a transistor, whose current carrying characteristics are affected by a voltage on a gate electrode. Field-effect transistors include junction field-effect transistors (JFETs) and metal-insulator-semiconductor field-effect transistors (MISFETs), including metal-oxide-semiconductor field-effect transistors (MOSFETs), metal-nitride-oxide-semiconductor (MNOS) field-effect transistors, or combinations thereof. A field-effect transistor can be n-channel (n-type carriers flowing within the channel region) or p-channel (p-type carriers flowing within the channel region). A field-effect transistor may be an enhancement-mode transistor (channel region having a different conductivity type compared to the source/drain regions of the same transistor) or depletion-mode transistor (channel and source/drain regions of the same transistor have the same conductivity type).

The term “fluorinated” when referring to an organic compound, is intended to mean that one or more of the hydrogen atoms in the compound have been replaced by fluorine. The term encompasses partially and fully fluorinated materials.

The term “organic active layer” is intended to mean one or more organic layers, wherein at least one of the organic layers, by itself or when in contact with a dissimilar material, is capable of forming a rectifying junction.

The term “organic electronic device” is intended to mean a device including one or more organic semiconductor layers or materials. An organic electronic device includes: (1) a device that convert electrical energy into radiation (e.g., a light-emitting diode, light emitting diode display, diode laser, or lighting panel), (2) a device that detects a signal through an electronic process (e.g., a photodetector, a photoconductive cell, a photoresistor, a photoswitch, a phototransistor, a phototube, an infrared (“IR”) detector, or a biosensor), (3) a device that converts radiation into electrical energy (e.g., a photovoltaic device or solar cell), and (4) a device that includes one or more electronic components that include one or more organic semiconductor layers (e.g., a transistor or diode).

The term “pixel” is intended to mean a portion of an array corresponding to one electronic component and its corresponding electronic component(s), if any, that are dedicated to that specific one electronic component. In one embodiment, a pixel has an OLED and its corresponding pixel driving circuit. Note that a pixel as used in this specification can be a pixel or subpixel as those terms are used by skilled artisans outside of this specification.

The term “pixel circuit” is intended to mean a circuit within a pixel. In one embodiment, the pixel circuit may be used in a display or a sensor array.

The term “pixel driving circuit” is intended to mean a circuit within a pixel that controls signal(s) for no more than one electronic component driven by such circuit.

The term “power supply line” is intended to mean a signal line having a primary function of transmitting power.

The term “reactive surface-active composition” is intended to mean a composition that comprises at least one material which is radiation sensitive, and when the composition is applied to a layer, the surface energy of that layer is reduced. Exposure of the reactive surface-active composition to radiation results in the change in at least one physical property of the composition. The term is abbreviated “RSA”, and refers to the composition both before and after exposure to radiation.

The term “rectifying junction” is intended to mean a junction within a semiconductor layer or a junction formed by an interface between a semiconductor layer and a dissimilar material in which charge carriers of one type flow easier in one direction through the junction compared to the opposite direction. A pn junction is an example of a rectifying junction that can be used as a diode.

The term “select line” is intended to mean a specific signal line within a set of signal lines having a primary function of transmitting one or more signals used to activate one or more electronic components, one or more circuits, or any combination thereof when the specific signal line is activated, wherein other electronic component(s), circuit(s), or any combination thereof associated with another signal line within the set of signal lines are not activated when the specific signal line is activated. The signals lines within the set of signal lines may or may not be activated as a function of time.

The term “select transistor” is intended to mean a transistor controlled by a signal on a select line.

The term “semiconductor” when referring to a material is intended to mean a material, which: (1) depending on impurity concentration(s) within the material, can be any of an insulator, a resistor, or a conductor; (2) when contacting a particular type of dissimilar material can form a rectifying junction; (3) is an active region of a transistor; or (4) any combination thereof. The term “signal” is intended to mean a current, a voltage, an optical signal, or any combination thereof. The signal can be a voltage or current from a power supply or can represent, by itself or in combination with other signal(s), data or other information. Optical signals can be based on pulses, intensity, or a combination thereof. Signals may be substantially constant (e.g., power supply voltages) or may vary over time (e.g., one voltage for on and another voltage for off).

The term “signal line” is intended to mean a line over which one or more signals may be transmitted. The signal to be transmitted may be substantially constant or vary. Signal lines can include control lines, data lines, scan lines, select lines, power supply lines, or any combination thereof. Note that signal lines may serve one or more principal functions.

The term “source/drain region” is intended to mean a region of a field-effect transistor that injects charge carriers into a channel region or receives charge carriers from the channel region. A source/drain region can include a source region or a drain region, depending on the flow of current through the field-effect transistor. A source/drain region may act as source region when current flows in one direction through the field-effect transistor, and as-a drain region when current flows in the opposite direction through the field-effect transistor.

The term “surface energy” is intended to mean the energy required to create a unit area of a surface from a material. A characteristic of surface energy is that liquid materials with a given surface energy will not wet surfaces with a lower surface energy.

The term “well structure” is intended to mean a structure overlying a substrate, wherein the structure serves a principal function of separating an object or region within or overlying the substrate from contacting a different object or different region within or overlying the substrate.

As used herein, the terms “comprises,” “comprising,” “includes,” “including,” “has,” “having” or any other variation thereof, are intended to cover a non-exclusive inclusion. For example, a process, method, article, or apparatus that comprises a list of elements is not necessarily limited to only those elements but may include other elements not expressly listed or inherent to such process, method, article, or apparatus. Further, unless expressly stated to the contrary, “or” refers to an inclusive or and not to an exclusive or. For example, a condition A or B is satisfied by any one of the following: A is true (or present) and B is false (or not present), A is false (or not present) and B is true (or present), and both A and B are true (or present).

Additionally, for clarity purposes and to give a general sense of the scope of the embodiments described herein, the use of the “a” or “an” are employed to describe one or more articles to which “a” or “an” refers. Therefore, the description should be read to include one or at least one whenever “a” or “an” is used, and the singular also includes the plural unless it is clear that the contrary is meant otherwise.

Group numbers corresponding to columns within the Periodic Table of the elements use the “New Notation” convention as seen in the CRC Handbook of Chemistry and Physics, 81^{st} Edition (2000).

Unless otherwise defined, all technical and scientific terms used herein have the same meaning as commonly understood by one of ordinary skill in the art to which this invention belongs. Although suitable methods and materials are described herein for embodiments of the invention, or methods for making or using the same, other methods and materials similar or equivalent to those described can be used without departing from the scope of the invention. All publications, patent applications, patents, and other references mentioned herein are incorporated by reference in their entirety. In case of conflict, the present specification, including definitions, will control. In addition, the materials, methods, and examples are illustrative only and not intended to be limiting.

To the extent not described herein, many details regarding specific materials, processing acts, and circuits are conventional and may be found in textbooks and other sources within the organic light-emitting diode display, photodetector, photovoltaic, and semiconductor arts.

2. Layer Formation and Layer Thickness

An organic layer can be formed by dispensing a liquid composition over a substrate or a workpiece. After dispensing the liquid composition, liquid medium or liquid media within the liquid composition evaporate, increasing the viscosity of the liquid composition and forming an organic layer. Surface tension, wetting angle, surface energy and viscosity within the liquid composition lead to variances in thickness of the organic layer across the organic layer.

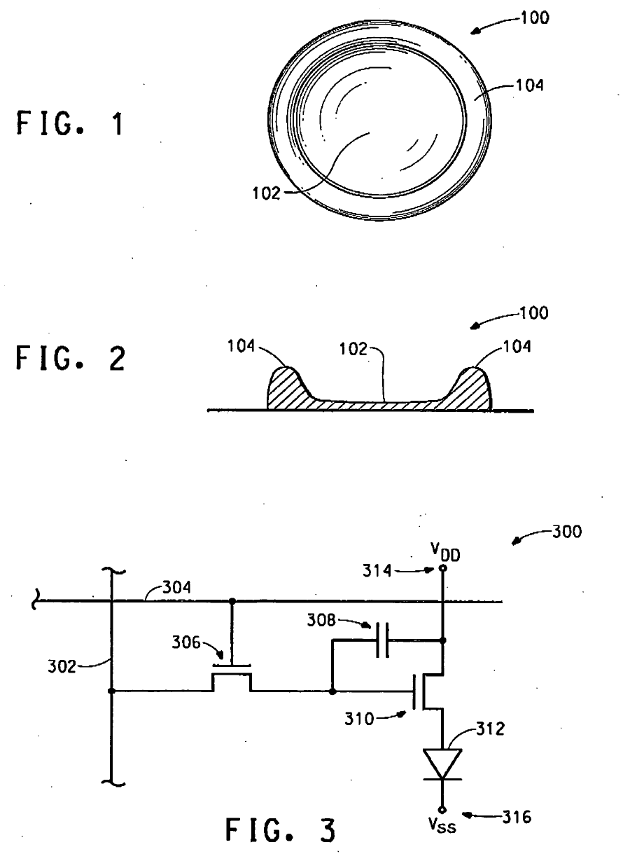

FIGS. 1 and 2 include a plan view illustration and a cross-sectional view illustration, respectively, of an exemplary organic layer. The exemplary organic layer 100 has significantly different thickness at locations within a center portion 102 than at locations within an edge portion 104. As illustrated in FIG. 2, the organic layer 100 at locations near the edge portion 104 is thicker than the organic layer 100 at locations within the center portion 102.

In one exemplary embodiment, the organic layer 100 at locations within the center portion 102 has a relatively uniform thickness. The thickness of the organic layer increases rapidly to a maximum when moving along the surface of the organic layer toward the edge portion 104 and drops from the maximum to an underlying interface when moving toward the outermost edge of the organic layer 100. Alternatively, the organic layer 100 has a relatively uniform center portion and a non-uniform edge portion, such as a thicker edge portion or thinner edge portion.

When such an organic layer is incorporated into electronic components, the thickness of the layer can affect performance characteristics of the electronic component. Thicker regions within an organic layer can reduce charge flow through the organic layer. For thinner regions within an organic active layer of radiation-emitting component, electrons and hole may recombine outside of the organic active layer, thereby reducing the radiation emitted from the organic active layer. For thinner regions within an organic active layer of radiation-responsive component, insufficient amounts of electrons and hole may be generated from the organic active layer.

In one particular embodiment, the organic layer 100 is an organic active layer. The thickness of the center portion 102 of the organic active layer is approximately 30 to 100 nm. The thickness of the edge portion 104 of the organic active layer may be as high as approximately 5000 nm. In one embodiment, the thickness of the edge portion 104 is not greater than 4000 nm. In another embodiment, the thickness is not greater than 3000 nm, and in still another embodiment, the thickness is not greater than 2000 nm. For example, the thickness of the edge portion 104 may be approximately 100 to 5000 nm, such as approximately 100 to 4000 nm, approximately 100 to 3000 nm, or approximately 100 to 2000 nm. In one exemplary embodiment, the ratio of thickness of the edge portion to the thickness of the center portion is 3:1 to 10:1. In another exemplary embodiment, the ratio of thickness of the edge portion to the thickness of the center portion is 1:3 to 1:10. Alternatively the organic layer 100 is selected from a group consisting of an organic active layer, a charge transport layer, a charge blocking layer, a charge injection layer or any combination thereof.

In some embodiments, the liquid composition includes at least one organic solvent and at least one material. For example, the liquid composition may include a solvent and between approximately 0.5% and 5% solids, such as between approximately 1% and 2% solids. The solids may include small organic molecules, polymers, or combinations thereof.

For a radiation-emitting organic active layer, a suitable radiation-emitting material includes one or more small molecule materials, one or more polymeric materials, or a combination thereof. Small molecule materials may include those described in, for example, U. S. Pat. No. 4,356,429 (“Tang”); U. S. Pat. No. 4,539,507 (“Van Slyke”); U.S. Patent Application Publication No. US 2002/0121638 (“Grushin”); and U. S. Pat. No. 6,459,199 (“Kido”). Alternatively, polymeric materials may include those described in U. S. Pat. No. 5,247,190 (“Friend”); U. S. Pat. No. 5,408,109 (“Heeger”); and U. S. Pat. No. 5,317,169 (“Nakano”). An exemplary material is a semiconducting conjugated polymer. An example of such polymers includes poly(paraphenylenevinylene) (PPV), a PPV copolymer, a polyfluorene, a polyphenylene, a polyacetylene, a polyalkylthiophene,-poly(n-vinylcarbazole) (PVK), or the like.

For a radiation-responsive organic active layer, a suitable radiation-responsive material may include many a conjugated polymer or an electroluminescent material. Such a material includes for example, a conjugated polymer or electro- and photo-luminescent material. A specific example includes poly(2-methoxy,5-(2-ethyl-hexyloxy)-1,4-phenylene vinylene) (“MEH-PPV”) or a MEH-PPV composite with CN-PPV.

Alternatively, an organic layer may be formed, such as a charge transport layer, a charge injection layer, a charge blocking layer or any combination thereof. For example, the organic layer may be a hole injection layer, a hole transport layer, an electron blocking layer, an electron injection layer, an electron transport layer, a hole blocking layer, or any combination thereof.

For a hole injection layer, hole transport layer, electron blocking layer, or any combination thereof, a suitable material includes polyaniline (“PANI”), poly(3,4-ethylenedioxythiophene) (“PEDOT”), a PANI or a PEDOT doped with protonic acids (e.g., poly(styrenesulfonic acid), poly(2-acrylamido-2-methyl-1-propanesulfonic acid), and the like), an organic charge transfer compound, such as copper phthalocyanine and tetrathiafulvalene tetracyanoquinodimethane (TTF-TCQN), a hole transport material as described in Kido, or any combination thereof.

In one embodiment, a hole injection layer, hole transport layer, electron blocking layer, or any combination thereof, is made from a dispersion of a conducting polymer and a colloid-forming polymeric acid. Such materials have been described in, for example, published U.S. Patent Applications 2004-0102577 and 2004-0127637.

Examples of hole transport materials have been summarized for example, in Kirk-Othmer Encyclopedia of Chemical Technology, Fourth Edition, Vol.18, p. 837-860,1996, by Y. Wang. Both hole transporting molecules and polymers can be used. Commonly used hole transporting molecules include, but are not limited to: 4,4′,4“-tris(N,N-diphenyl-amino)-triphenylamine (TDATA); 4,4′,4”-tris(N-3-methylphenyl-N-phenyl-amino)-triphenylamine (MTDATA); N,N′-diphenyl-N,N′-bis(3-methylphenyl)-[1,1′-biphenyl] 4,4′-diamine (TPD); 1,1-bis[(di-4tolylamino) phenyl]cyclohexane (TAPC); N,N′-bis(4-methylphenyl)-N,N′-bis(4-ethylphenyl)-[1,1′-(3,3′-dimethyl)biphenyl]4,4′-diamine (ETPD); tetrakis-(3-methylphenyl)-N,N,N′,N′-2,5-phenylenediamine (PDA); a-phenyl-4-N,N-diphenylaminostyrene (TPS); p-(diethylamino)benzaldehyde diphenylhydrazone (DEH); triphenylamine (TPA); bis[4-(N,N-diethylamino) -2-methylphenyl](4-methylphenyl)methane (MPMP); 1-phenyl-3-[p-(diethylamino)styryl]-5-[p-(diethylamino)phenyl] pyrazoline (PPR or DEASP); 1,2-trans-bis(9H-carbazol-9-yl)cyclobutane (DCZB); N,N,N′, N′-tetrakis(4-methylphenyl)-(1,1′-biphenyl)-4,4′-diamine (TTB); N,N′-bis(naphthalen-1-yl)-N,N′-bis-(phenyl)benzidine (α-NPB); and porphyrinic compounds, such as copper phthalocyanine. Commonly used hole transporting polymers include, but are not limited to, polyvinylcarbazole, (phenylmethyl)polysilane, poly(dioxythiophenes), polyanilines, and polypyrroles. It is also possible to obtain hole transporting polymers by doping hole transporting molecules such as those mentioned above into polymers such as polystyrene and polycarbonate.

For an electron injection layer, electron transport layer, hole blocking layer, or any combination thereof, a suitable material includes a metal-chelated oxinoid compound (e.g., Alq₃); phenanthroline-based compounds (e.g., 2,9-dimethyl4,7-diphenyl-1,10-phenanthroline (“DDPA”), 4,7-diphenyl-1,10-phenanthroline (“DPA”)); an azole compound (e.g., 2-(4-biphenyl)-5-(4-t-butylphenyl)-1,3,4-oxadiazole (“PBD”), 3-(4-biphenyl)4-phenyl-5-(4-t-butylphenyl)-1,2,4-triazole (“TAZ”); an electron-transport material as described in Kido; or any combination thereof.

For an electronic component, such as a resistor, transistor, capacitor, etc., the organic layer may include one or more of thiophenes (e.g., polythiophene, poly(alkylthiophene), alkylthiophene, bis(dithienthiophene), alkylanthradithiophene, etc.), polyacetylene, pentacene, phthalocyanine, or any combination thereof.

An example of an organic dye includes 4-dicyanmethylene-2-methyl -6- (p-dimethyaminostyryl)4H-pyran (DCM), coumarin, pyrene, perylene, rubrene, derivatives thereof, or any combination thereof.

An example of an organometallic material includes a functionalized polymer comprising a functional group coordinated to at least one metal. An exemplary functional group contemplated for use includes a carboxylic acid, carboxylic acid salt, sulfonic acid group, sulfonic acid salt, a group having an OH moiety, an amine, a imine, diimine, a N-oxide, a phosphine, a phosphine oxide, a β-dicarbonyl group, or any combination thereof. An exemplary metal contemplated for use includes a lanthanide metal (e.g., Eu, Tb), a Group 7 metal (e.g., Re), a Group 8 metal (e.g., Ru, Os), a Group 9 metal (e.g., Rh, Ir), a Group 10 metal (e.g., Pd, Pt), a Group 11 metal (e.g., Au), a Group 12 metal (e.g., Zn), a Group 13 metal (e.g., Al), or any combination thereof. Such an organometallic material includes a metal chelated oxinoid compound, such as a tris(8-hydroxyquinolato)aluminum (Alq₃); a cyclometalated iridium, and a platinum electroluminescent compound, such as a complex of an iridium with a phenylpyridine, a phenylquinoline, or a phenylpyrimidine ligand, as disclosed in published PCT Application WO 02/02714, or any an organometallic complex described in, for example, published applications US 2001/0019782, EP 1191612, WO 02/15645, WO 02/31896, and EP 1191614; or any mixture thereof.

An example of a conjugated polymer includes poly(phenylenevinylene), polyfluorene, poly(spirobifluorene), copolymer thereof, or any mixture thereof.

Selecting a liquid medium or media can also be a factor for achieving the proper characteristics of the liquid composition. A factor to be considered when choosing a liquid medium (media) includes, for example, viscosity of the resulting solution, emulsion, suspension, or dispersion, molecular weight of a polymeric material, solids loading, type of liquid medium, vapor pressure of the liquid medium, temperature of an underlying substrate, thickness of an organic layer that receives a guest material, or any combination thereof

The liquid composition can include at least one organic solvent. An exemplary organic solvent includes a halogenated solvent, a hydrocarbon solvent, an aromatic hydrocarbon solvent, an ether solvent, a cyclic ether solvent, an alcohol solvent, a ketone solvent, an acetate solvent, a nitrile solvent, a sulfoxide solvent, an amide solvent, or any combination thereof.

An exemplary halogenated solvent includes carbon tetrachloride, methylene chloride, chloroform, tetrachloroethylene, chlorobenzene, bis(2-chloroethyl)ether, chloromethyl ethyl ether, chloromethyl methyl ether, 2-chloroethyl ethyl ether, 2-chloroethyl propyl ether, 2-chloroethyl methyl ether, or any combination thereof.

An exemplary hydrocarbon solvent includes pentane, hexane, cyclohexane, heptane, octane, decahydronaphthalene, petroleum ether, ligroine, or any combination thereof.

An exemplary aromatic hydrocarbon solvent includes benzene, naphthalene, toluene, xylene, ethyl benzene, cumene (iso-propyl benzene) mesitylene (trimethyl benzene), ethyl toluene, butyl benzene, cymene (iso-propyl toluene), diethylbenzene, iso-butyl benzene, tetramethyl benzene, sec-butyl benzene, tert-butyl benzene, anisole, or any combination thereof.

An exemplary ether solvent includes diethyl ether, ethyl propyl ether, dipropyl ether, diisopropyl ether, dibutyl ether, methyl t-butyl ether, glyme, diglyme, benzyl methyl ether, isochroman, 2-phenylethyl methyl ether, n-butyl ethyl ether, 1,2-diethoxyethane, sec-butyl ether, diisobutyl ether, ethyl n-propyl ether, ethyl isopropyl ether, n-hexyl methyl ether, n-butyl methyl ether, methyl n-propyl ether, or any combination thereof.

An exemplary cyclic ether solvent suitable includes tetrahydrofuran, dioxane, tetrahydropyran, 4 methyl-1,3-dioxane, 4-phenyl-1,3-dioxane, 1,3-dioxolane, 2-methyl-1,3-dioxolane, 1,4-dioxane, 1,3-dioxane, 2,5-dimethoxytetrahydrofuran, 2,5-dimethoxy-2,5-dihydrofuran, or any combination thereof.

An exemplary alcohol solvent includes methanol, ethanol, 1-propanol, 2-propanol, 1-butanol, 2-butanol, 2-methyl-1-propanol (i.e., iso-butanol), 2-methyl-2-propanol (i.e., tert-butanol), 1-pentanol, 2-pentanol, 3-pentanol, 2,2-dimethyl-1-propanol, 1-hexanol, cyclopentanol, 3-methyl-1-butanol, 3-methyl-2-butanol, 2-methyl-1-butanol, 2,2-dimethyl-1-propanol, 3-hexanol, 2-hexanol, 4-methyl-2-pentanol, 2-methyl-1-pentanol, 2-ethylbutanol, 2,4-dimethyl-3-pentanol, 3-heptanol, 4-heptanol, 2-heptanol, 1-heptanol, 2-ethyl-1-hexanol, 2,6-dimethyl4-heptanol, 2-methylcyclohexanol, 3-methylcyclohexanol, 4-methylcyclohexanol, or any combination thereof.

An alcohol ether solvent may also be employed. An exemplary alcohol ether solvent includes 1-methoxy-2-propanol, 2-methoxyethanol, 2-ethoxyethanol, 1-methoxy-2-butanol, ethylene glycol monoisopropyl ether, 1-ethoxy-2-propanol, 3-methoxy-l-butanol, ethylene glycol monoisobutyl ether, ethylene glycol mono-n-butyl ether, 3-methoxy-3-methylbutanol, ethylene glycol mono-tert-butyl ether, ethylene glycol monomethyl ether, propylene glycol monomethyl ether, or any combination thereof.

An exemplary ketone solvent includes acetone, methylethyl ketone, methyl iso-butyl ketone, cyclopentanone, cyclohexanone, isopropyl methyl ketone, 2-pentanone, 3-pentanone, 3-hexanone, diisopropyl ketone, 2-hexanone, cyclopentanone, 4-heptanone, iso-amyl methyl ketone, 3-heptanone, 2-heptanone, 4-methoxy4-methyl-2-pentanone, 5-methyl-3-heptanone, 2-methylcyclohexanone, diisobutyl ketone, 5-methyl-2-octanone, 3-methylcyclohexanone, 2-cyclohexen-1-one, 4-methylcyclohexanone, cycloheptanone, 4-tert-butylcyclohexanone, isophorone, benzyl acetone, or any combination thereof.

An exemplary acetate solvent includes ethylene glycol monomethyl ether acetate, propylene glycol monomethyl ether acetate, or any combination thereof.

An exemplary nitrile solvent includes acetonitrile, acrylonitrile, trichloroacetonitrile, propionitrile, pivalonitrile, isobutyronitrile, n-butyronitrile, methoxyacetonitrile, 2-methylbutyronitrile, isovaleronitrile, N-valeronitrile, n-capronitrile, 3-methoxypropionitrile, 3-ethoxypropionitrile, 3,3′-oxydipropionitrile, n-heptanenitrile, glycolonitrile, benzonitrile, ethylene cyanohydrin, succinonitrile, acetone cyanohydrin, 3-n-butoxypropionitrile, or any combination thereof.

An exemplary sulfoxide solvent suitable includes dimethyl sulfoxide, di-n-butyl sulfoxide, tetramethylene sulfoxide, methyl phenyl sulfoxide, or any combination thereof.

An exemplary amide solvent suitable includes dimethyl formamide, dimethyl acetamide, acylamide, 2-acetamidoethanol, N,N-dimethyl-m-toluamide, trifluoroacetamide, N,N-dimethylacetamide, N,N-diethyldodecanamide, epsilon-caprolactam, N, N-diethylacetamide, N-tert-butylformamide, formamide, pivalamide, N-butyramide, N,N-dimethylacetoacetamide, N-methyl formamide, N,N-diethylformamide, N-formylethylamine, acetamide, N,N-diisopropylformamide, 1-formylpiperidine, N-methylformanilide, or any combination thereof.

A crown ether contemplated includes all crown ethers that can function to assist in the reduction of the chloride content of an epoxy compound starting material as part of the combination being treated according to the invention. An exemplary crown ether includes benzo-15-crown-5; benzo-18-crown-6; 12-crown4; 15-crown-5; 18-crown-6; cyclohexano-15-crown-5; 4′,4″ (5″)-ditert-butyldibenzo-18-crown-6; 4′,4″(5″)-ditert-butyldicyclohexano-18-crown-6; dicyclohexano-18-crown-6; dicyclohexano-24-crown-8; 4′-aminobenzo-15-crown-5; 4′-aminobenzo-18-crown-6; 2-(aminomethyl)-15-crown-5; 2-(aminomethyl)-18-crown-6; 4′-amino-5′-nitrobenzo-15-crown-5; 1-aza-12-crown4; 1-aza-15-crown-5; 1-aza-18-crown-6; benzo-12-crown4; benzo-15-crown-5; benzo-18-crown-6; bis((benzo-15-crown-5)-15-ylmethyl)pimelate; 4-bromobenzo-18-crown-6; (+)-(18-crown-6)-2,3,11,12-tetra-carboxylic acid; dibenzo-18-crown-6; dibenzo-24-crown-8; dibenzo-30-crown-10; ar-ar′-di-tert-butyldibenzo-18-crown-6; 4′-formylbenzo-15-crown-5; 2-(hydroxymethyl)-12-crown4; 2-(hydroxymethyl) -15-crown-5; 2-(hydroxymethyl)-18-crown-6; 4′-nitrobenzo-15-crown-5; poly-[(dibenzo-18-crown-6)-co-formaldehyde]; 1,1-dimethylsila -11-crown-4; 1,1-dimethylsila-14-crown-5; 1,1-dimethylsila-17-crown-5; cyclam; 1,4,10,13-tetrathia-7,16-diazacyclooctadecane; porphines; or any combination thereof.

In another embodiment, the liquid medium includes water. A conductive polymer complexed with a water-insoluble colloid-forming polymeric acid can be deposited over a substrate and used as a charge transport layer.

Many different classes of liquid media (e.g., halogenated solvents, hydrocarbon solvents, aromatic hydrocarbon solvents, water, etc.) are described above. A mixture of more than one of the liquid media from different classes may also be used.

3. Electronic Devices and Processes for Forming Such Electronic Devices

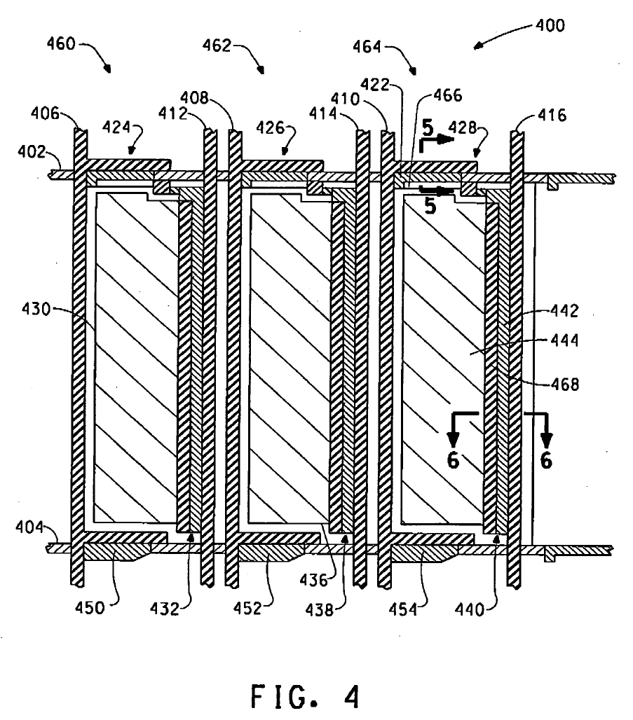

An electronic device includes an array of pixels. Each of the pixels can include the circuit 300 as illustrated in FIG. 3, such as in an active matrix OLED device. In one embodiment, the circuit 300 is a pixel circuit. In another embodiment, the electronic device includes a monochromatic display, and therefore, each pixel includes one circuit 300. In still another embodiment, the electronic device includes a full color display that includes a set of three pixels. Each of the pixels includes one circuit 300.

A very large number of pixel circuits can be used. In one embodiment, a basic circuit design, such as that illustrated in FIG. 3, includes a two transistor, one capacitor (2T-1C) design. The transistors may be n-channel, p-channel, or a combination thereof. One transistor is a select transistor, and the other transistor is a driving transistor. Typically, the transistors are TFTs.

The circuit 300 includes a select transistor 306, a capacitive electronic component 308, and a driving transistor 310. A select line 304 is coupled to a gate electrode of the select transistor 306, and a data line 302 is coupled to a first terminal of the select transistor 306. A second terminal of the select transistor 306 is coupled to a first electrode of a capacitive electronic component 308, such as a capacitor, and a gate electrode of the driving transistor 310.

A V_{DD} power supply line 314 is coupled to a second electrode of the capacitor 308 and a first terminal of the driving transistor 310. A second terminal of the driving transistor 310 can be coupled to a first electrode of an electronic component 312. The electronic component 312 includes the first electrode and a second electrode that is connected to a Vₛₛ power supply line 316. In one embodiment, the first electrode is an anode, and the second electrode is a cathode. In another embodiment, the electronic component 312 is an organic, radiation-emitting electronic component, such as an OLED.

When the select line 304 is activated, the transistor 306 is activated, allowing data from the data line 302 to pass. The data line 302 may be at a positive voltage, a negative voltage, or at zero volts depending on the desired state of the pixel and type of the driving transistor 310 (i.e., n-channel or p-channel). As a result, the capacitive electronic component 308 may accumulate charge, dissipate charge, or remain at its current state. The degree to which the driving transistor 310 is activated depends on the voltage of the data line 302.

FIGS. 4 through 10 include illustrations of an exemplary process for forming an electronic device. FIG. 4 includes a plan view illustration of a portion of an array 400. In one exemplary embodiment, the array 400 includes three pixels 460, 462, and 464. In one embodiment, electronic components of pixels 460, 462, and 464 of the array 400 may, when complete and activated, emit radiation, such as visible light, with emission profiles having emission maxima at different wavelengths. For example, the pixel 460 can be configured to emit red light, the electronic component 462 can be configured to emit green light, and the electronic component 464 can be configured to emit blue light. In alternative embodiments, each component may be configured to emit the same color light, such as in a monochrome display.

In a particular embodiment, the array 400 is free of overlying well structures. In an alternative embodiment, well structures that have openings that expose the electrodes and at least a portion of the pixel driving circuit can be included. Embodiments including well structures are described in more detail in U.S. patent application Ser. No. 11/313,131 entitled “Improved pixel intensity homogeneity in organic electronic devices” by Stainer et al. filed Dec. 20, 2005, which is incorporated herein by reference in its entirety.

In the exemplary embodiment illustrated in FIG. 4, each pixel 460, 462, and 464 has an associated pixel driving circuit including a select transistor 424, 426, or 428, a capacitive electronic component (not shown), and a driving transistor 432, 438, or 440. A first select line 402 is connected to the pixel driving circuits of each pixel 460, 462, and 464, such as to the gate electrodes of the select transistors 424, 426, and 428. In addition, the data lines 406, 408, and 410 are connected to one of the pixel driving circuits of pixels 460, 462, and 464, respectively, such as to first terminals of the select transistors 424, 426, and 428, respectively. In addition, the V_{DD} power supply lines 412, 414, and 416 are connected to the pixel driving circuits of the pixels 460, 462, and 464, respectively, such as to first terminals of the driving transistors 432, 438, and 440, respectively.

For example, exemplary pixel 464 includes a pixel driving circuit including a select transistor 428, a capacitive electronic component (not shown), and a driving transistor 440. A portion of the select line 402 is the gate electrode of the select transistor 428 and the data line 410 is connected to a first terminal of the select transistor 428. A second terminal of the select transistor 428 is connected to a first electrode of a capacitor (not shown) and the gate electrode of the driving transistor 440. The V_{DD} power supply line 416 is connected to a first terminal of the driving transistor 440.

A first electrode 444 is connected to a second terminal of the driving transistor 440. For example, the first electrode 444 is an anode that is connected to the second terminal of the driving transistor 440.

In this example, the first select line 402 may also be connected to other pixels and electronic components to the left and the right within the array 400, but are not illustrated in FIG. 4. The data lines 406, 408, and 410 and the V_{DD} power supply lines 412, 414, and 416 may also be connected to pixels and electronic components above and below the pixels 460, 462, and 464, as illustrated in FIG. 4. For example, the data lines 406, 408, and 410 may be connected to the select transistors 450, 452 and 454, respectively. A second select line 404 can be connected to the gate electrodes of each select transistor 450, 452, and 454. The second select line 404 is not connected to the pixel driving circuit of the exemplary pixel 464.

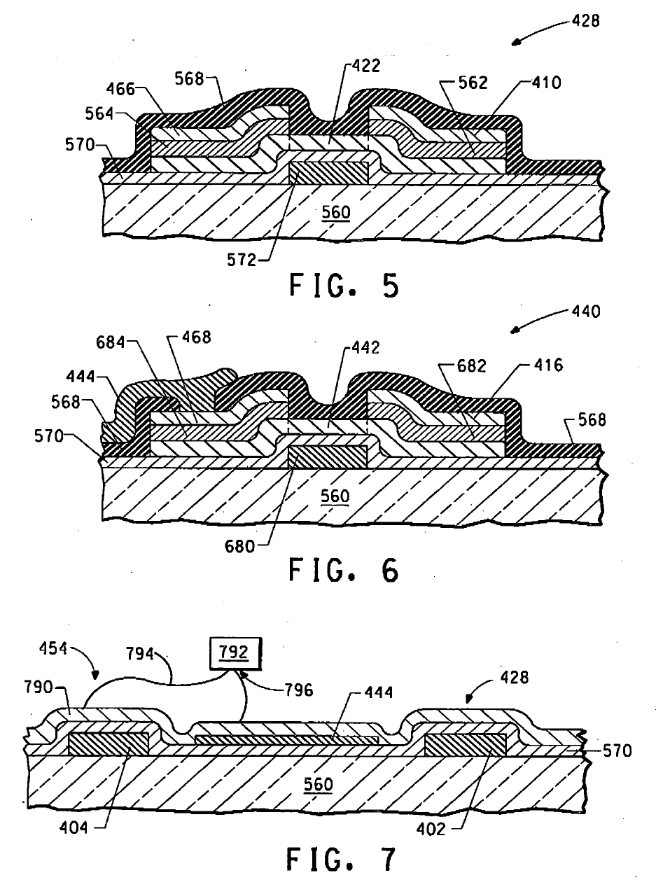

FIG. 5 includes a cross-sectional illustration of the select transistor 428. The first select line 402 overlies a substrate 560 and includes a gate electrode 572 of the select transistor 428.

The substrate 560 can be rigid or flexible and may contain one or more layers of an organic, inorganic, or both organic and inorganic materials. In one embodiment, the substrate 560 includes a transparent material that allows at least 70% of the radiation incident on the substrate 560 to be transmitted through it.

The gate electrode 572 may include one or more layers that include at least one element selected from Groups 4-6, 8 and 10-14 of the Periodic Table. In one embodiment, the exposed conductors can include Cu, Al, Ag, Au, Mo, or any combination thereof. In another embodiment, where the gate electrode 572 includes more than one layer, one of the layers can include Cu, Al, Ag, Au, Mo, or any combination thereof, and another layer can include Mo, Cr, Ti, Ru, Ta, W, Si, or any combination thereof. Note that conductive metal oxide(s), conductive metal nitride(s) or a combination thereof may be used in place of or in conjunction with any of elemental metal or alloy thereof. In one embodiment, the gate electrode 572 has a thickness in a range of approximately 0.2 to 5 microns.

Layer 570 overlies the select line 402 and acts as a gate dielectric layer. Layer 570 can include one or more layers including silicon dioxide, alumina, hafnium oxide, silicon nitride, aluminum nitride, silicon oxynitride, another conventional gate dielectric material as used in the semiconductor arts, or any combination thereof. In one embodiment, thickness of the layer 570 is in a range of approximately 50-1000 nm.

A channel layer 422 overlies the layer 570. The channel layer 422 can include one or more materials conventionally used as semiconductors in electronic components. In one embodiment, the channel layer 422 is formed (e.g., deposited) as amorphous silicon (a—Si), low-temperature polysilicon (LTPS), continuous grain silicon (CGS), or any combination thereof. In another embodiment, another Group 14 element (e.g., carbon, germanium), by itself or in combination (with or without silicon), may be used for the channel layer 422. In still another embodiment, the channel layer 422 includes one or more Ill-V (Group 13-Group 15) semiconductors (e.g., GaAs, InP, GaAIAs, etc.), one or more Il-VI (Group 2-Group 16 or Group 12-Group 16) semiconductors (e.g., CdTe, CdSe, CdZnTe, ZnSe, ZnTe, etc.), or any combination thereof.

The channel layer 422 is undoped or has n-type or p-type dopant at a concentration no greater than approximately 1×10¹⁹ atoms/cm³. A conventional n-type dopant (phosphorous, arsenic, antimony, etc.) or a p-type dopant (boron, gallium, aluminum, etc.) can be used. Such dopant can be incorporated during deposition or added during a separate doping sequence (e.g., implanting and annealing). The channel layer 422 is formed using conventional deposition and doping techniques. In one embodiment, the thickness of the channel layer 422 is in a range of approximately 30 to 550 nm. The dashed portion is the channel region. After reading this specification, skilled artisans will appreciate that other thicknesses may be used to achieve the desired electronic characteristics of the select transistor 428.

Source/drain regions 562 and 564 overlie channel layer 422. In one embodiment, the source/drain regions 562 and 564 are n+or p+doped in order to form ohmic contacts with subsequently formed metal-containing structures. In another embodiment, the dopant concentration within the source/drain regions 562 and 564 are less than 1×10¹⁹ atoms/cm³ and form Schottky contacts would be formed when contacted with subsequently formed metal-containing structures. A conventional n-type dopant (phosphorous, arsenic, antimony, etc.) or a p-type dopant (boron, gallium, aluminum, etc.) can be used. In one exemplary embodiment, the source/drain regions 562 and 564 are formed from a single layer and etched to form two elements.

In the exemplary embodiment illustrated in FIGS. 4 and 5, the data line 410 is connected to and overlies the source/drain region 562 of select transistor 428. The interconnect layer 466 is connected to and overlies the source/drain region 564 of the select transistor 428. The insulating layer 568 (not shown in FIG. 4) overlies the select transistor 428 and can include insulating material such as those described in relation to the layer 570. The interconnect layer 466 is connected to an electrode of a capacitive electronic element (not shown) and the gate electrode 680 of the driving transistor 440. FIG. 6 includes a cross-sectional view illustration of the driving transistor 440. The gate electrode 680 overlies the substrate 560. The channel layer 442 overlies the layer 570 and the gate electrode 680. Dashed portion is a channel region. Source/drain regions 682 and 684 of the driving transistor 440 overlie portions of the channel layer 442. The source/drain regions 562 and 564 and the source/drain regions 682 and 684 may be formed from the same or different layers. The V_{DD} power supply line 416 overlies the source/drain region 682. An interconnect layer 468 that is connected to first electrode 444, overlies and is connected to the source/drain region 684. The layers of the driving transistor 440 may be formed of conventional materials using conventional techniques, as described above.

The insulating layer 568 can be formed by depositing conventional materials and patterning them to overlie the layers and leave access to the interconnect layer 468. The access through the insulating layer 568 allows contact between the interconnect layer 468 and the electrode 444. In one exemplary embodiment, the first electrode 444 overlies at least part of the pixel driving circuitry, such as a portion of the driving transistor 440.

Once the pixel driving circuit has been formed, an organic layer is deposited over the first electrode 444 and, at least in part, over the pixel driving circuit. An optional layer 790 may overlie, the electrode 444 and pixel driving circuit. FIG. 7 includes a cross-sectional view illustration of dispensing an organic layer over an electrode 444 and the optional layer 790. The optional layer 790 can include one or more of a charge transport layer, a charge blocking layer, and a charge injection layer formed of conventional materials using conventional techniques. In an alternative embodiment, the optional layer 790 may be dispensed using a continuous dispense method.

After forming the optional layer 790, a continuous dispense nozzle 792 having an opening or aperture 796 dispenses a continuous stream 794 of liquid composition over the electrode 444 and the optional layer 790. In addition, the liquid composition may be dispensed to at least partially overlie the select transistor 454 and the select transistor 428. In an alternative embodiment, the continuous stream 794 of the liquid composition may be dispensed along a row or column of electrodes, such as over the electrode 444 and electrodes above and below the electrode 444 when viewed from the plan view illustrated in FIG. 4. However, the liquid composition is not dispensed over the electrodes 430 and 436 within the adjacent pixels 460 and 462 in this embodiment.

In one exemplary embodiment, the continuous dispense nozzle 792 is configured to dispense the continuous stream 794 of the liquid composition over the electrode 444 and at least in part over the pixel driving circuit, such as the select transistors 454 and 428, at a rate of at least 100 centimeters per second along a print path. For example, when dispensing, the continuous dispense nozzle 792 is configured to move such that a continuous stream 794 of the liquid composition is deposited at a rate of at least approximately 100 centimeters per second, such as at least one meter per second, at least three meters per second, or at least six meters per second.

In another exemplary embodiment, the continuous dispense nozzle 792 may be configured to dispense liquid at a rate greater than 10 microliters per minute. In another embodiment the rate is approximately 50 microliters per minute or higher. In still another embodiment, the rate is approximately 100 microliters per minute or higher. The size of the aperture 796 may be selected based on the conditions and parameters of the dispense action. Generally, the aperture 796 has a diameter of approximately 5 microns to 30 microns. In one embodiment, the diameter is approximately 10 microns to 20 microns.

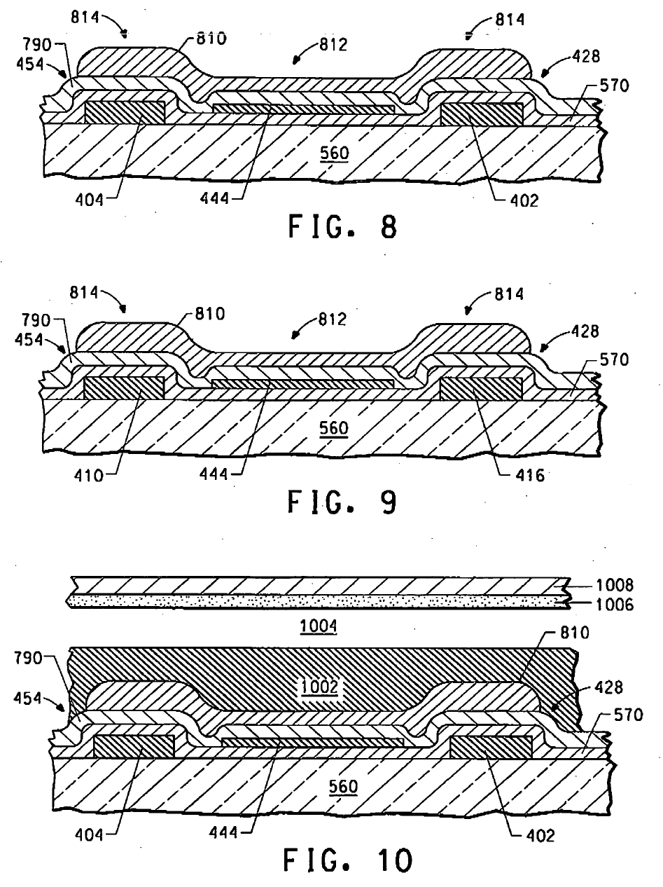

As the liquid medium or liquid media of the liquid composition evaporates, the viscosity of the liquid composition increases and an organic layer is formed. For example, FIGS. 8 and 9 include cross-sectional view illustrations along orthogonal axes through the electrode 444. As illustrated in FIG.8, the organic layer 810 formed from the liquid composition has a center portion 812 that overlies the electrode 444 and edge portions 814 that, at least partially overlie the transistors 454 and 428. As illustrated in FIG. 9, the organic layer 810 at least partially overlies the data line 410 and the transistor 440. The organic layer 810 may at least partially overlie the pixel driving circuit including the select line 402, the data line 410, the V_{DD} power supply line 416 and the select line 404.

In this exemplary embodiment, the edge portions 814 are thicker than the center portion 812. The center portion 812 has relatively uniform thickness and overlies all of the electrode 444.

In this exemplary embodiment, the pixel is free of well structures. As such, the organic layer 810 does not contact a well structure. Yet, the organic layer 810 does not overflow the pixel 460 to lie within adjacent components, such as the electronic component of adjacent pixel 462 illustrated in FIG. 4. In a specific embodiment, described in more detail later in this specification, the surface energy of the area between adjacent electronic components (e.g., pixels 460, 462, and 464) can be modified to help prevent overflow of organic layer 810 into adjacent electronic components.

In one exemplary embodiment (not illustrated), a second organic layer having a different composition from the first organic layer 810 is formed over another electrode, such as the electrode 436, and has an edge portion and a center portion. The edge portion of the second organic layer has a different thickness than the center portion, such as a thicker edge portion. For example, the center portion may have a thickness approximately 30-100 nm and the edge portion may have a thickness approximately 100-5000 nm. The second organic layer can at least partially overlie surrounding circuitry including the driving transistor 432, the select transistor 426, the select transistor 452, the driving transistor 438, the select line 402, the select line 404, the V_{DD} power supply line 414, and the data line 408.

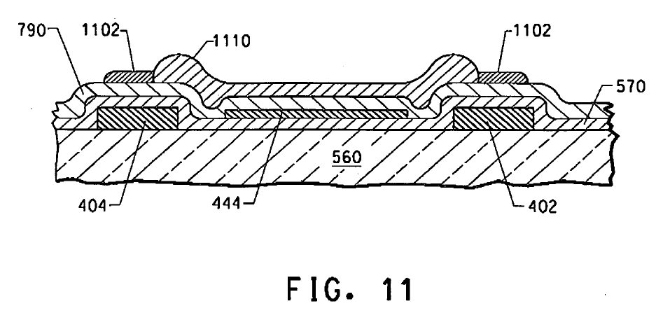

FIG. 10 includes a cross-sectional view illustration of a process in the formation of a substantially completed electronic device. A second electrode 1002 overlies the organic layer 810. A lid 1008 with a desiccant 1006 is attached to the substrate 560 at location not illustrated in FIG. 10. A gap 1004 may or may not lie between the second electrode 1002 and the desiccant 1006.

Generally, the layers, such as those described in relation to conductive lines, electrodes, transistors, and capacitors, are formed from conventional materials using conventional techniques.

4. Alternative Embodiments

In an alternative embodiment, a reactive surface-active composition (“RSA”) may be used to alter the surface energy of a layer before deposition of an organic layer. This can help limit the spreading of a liquid composition over a substrate or a workpiece. For example, when depositing liquid compositions to make a full-color display, it can be important to prevent color mixing of the separate R, G, and B pixels due to spreading of the liquid compositions after deposition. In one embodiment, before a liquid composition is deposited to form an organic layer, an RSA can be deposited to prevent spreading of the liquid composition from one pixel to a neighboring pixel. Concepts related to the use of an RSA and other similar principles are described in more detail in U.S. patent application Ser. No. 11/401,151 entitled “Process for making contained layers and devices made with same” by Lang et al. filed Apr. 10, 2006, which is incorporated herein by reference in its entirety.

The RSA is a radiation-sensitive composition. When exposed to radiation, at least one physical property and/or chemical property of the RSA is changed such that the exposed and unexposed areas can be physically differentiated. Treatment with the RSA lowers the surface energy of the material being treated.

In one embodiment, the RSA is a radiation-hardenable composition. In this case, when exposed to radiation, the RSA can become more soluble or dispersable in a liquid medium, less tacky, less soft, less flowable, less liftable, or less absorbable. Other physical properties may also be affected.

In one embodiment, the RSA is a radiation-softenable composition. In this case, when exposed to radiation, the RSA can become less soluble or dispersable in a liquid medium, more tacky, more soft, more flowable, more liftable, or more absorbable. Other physical properties may also be affected.

The radiation can be any type of radiation to which results in a physical change in the RSA. In one embodiment, the radiation is selected from infrared radiation, visible radiation, ultraviolet radiation, and combinations thereof.

Physical differentiation between areas of the RSA exposed to radiation and areas not exposed to radiation, hereinafter referred to as “development,” can be accomplished by any known technique. Such techniques have been used extensively in the photoresist art. Examples of development techniques include, but are not limited to, treatment with a liquid medium, treatment with an absorbant material, treatment with a tacky material, and the like.

In one embodiment, the RSA consists essentially of one or more radiation-sensitive materials. In one embodiment, the RSA consists essentially of a material which, when exposed to radiation, hardens, or becomes less soluble, swellable, or dispersible in a liquid medium, or becomes less tacky or absorbable. In one embodiment, the RSA consists essentially of a material having radiation polymerizable groups. Examples of such groups include, but are not limited to olefins, acrylates, methacrylates and vinyl ethers. In one embodiment, the RSA material has two or more polymerizable groups which can result in crosslinking. In one embodiment, the RSA consists essentially of a material which, when exposed to radiation, softens, or becomes more soluble, swellable, or dispersible in a liquid medium, or becomes more tacky or absorbable. In one embodiment, the RSA consists essentially of at least one polymer which undergoes backbone degradation when exposed to deep UV radiation, having a wavelength in the range of 200-300 nm. Examples of polymers undergoing such degradation include, but are not limited to, polyacrylates, polymethacrylates, polyketones, polysulfones, copolymers thereof, and mixtures thereof.

In one embodiment, the RSA consists essentially of at least one reactive material and at least one radiation-sensitive material. The radiation-sensitive material, when exposed to radiation, generates an active species that initiates the reaction of the reactive material. Examples of radiation-sensitive materials include, but are not limited to, those that generate free radicals, acids, or combinations thereof. In one embodiment, the reactive material is polymerizable or crosslinkable. The material polymerization or crosslinking reaction is initiated or catalyzed by the active species. The radiation-sensitive material is generally present in amounts from 0.001% to 10.0% based on the total weight of the RSA.

In one embodiment, the RSA consists essentially of a material which, when exposed to radiation, hardens, or becomes less soluble, swellable, or dispersible in a liquid medium, or becomes less tacky or absorbable. In one embodiment, the reactive material is an ethylenically unsaturated compound and the radiation-sensitive material generates free radicals. Ethylenically unsaturated compounds include, but are not limited to, acrylates, methacrylates, vinyl compounds, and combinations thereof. Any of the known classes of radiation-sensitive materials that generate free radicals can be used. Examples of radiation-sensitive materials which generate free radicals include, but are not limited to, quinones, benzophenones, benzoin ethers, aryl ketones, peroxides, biimidazoles, benzyl dimethyl ketal, hydroxyl alkyl phenyl acetophone, dialkoxy actophenone, trimethylbenzoyl phosphine oxide derivatives, aminoketones, benzoyl cyclohexanol, methyl thio phenyl morpholino ketones, morpholino phenyl amino ketones, alpha halogennoacetophenones, oxysulfonyl ketones, sulfonyl ketones, oxysulfonyl ketones, sulfonyl ketones, benzoyl oxime esters, thioxanthrones, camphorquinones, ketocoumarins, and Michler's ketone. Alternatively, the radiation sensitive material may be a mixture of compounds, one of which provides the free radicals when caused to do so by a sensitizer activated by radiation. In one embodiment, the radiation sensitive material is sensitive to visible or ultraviolet radiation.

In one embodiment, the RSA is a compound having one or more crosslinkable groups. Crosslinkable groups can have moieties containing a double bond, a triple bond, a precursor capable of in situ formation of a double bond, or a heterocyclic addition polymerizable group. Some examples of crosslinkable groups include benzocyclobutane, azide, oxiran, di(hydrocarbyl)amino, cyanate ester, hydroxyl, glycidyl ether, C1-10 alkylacrylate, C1-10 alkylmethacrylate, alkenyl, alkenyloxy, alkynyl, maleimide, nadimide, tri(C1-4)alkylsiloxy, tri(C1-4)alkylsilyl, and halogenated derivatives thereof. In one embodiment, the crosslinkable group is selected from the group consisting of vinylbenzyl, p-ethenylphenyl, perfluoroethenyl, perfluoroethenyloxy, benzo-3,4-cyclobutan -1-yl, and p-(benzo-3,4-cyclobutan-1-yl)phenyl.

In one embodiment, the reactive material can undergo polymerization initiated by acid, and the radiation-sensitive material generates acid. Examples of such reactive materials include, but are not limited to, epoxies. Examples of radiation-sensitive materials which generate acid, include, but are not limited to, sulfonium and iodonium salts, such as diphenyliodonium hexafluorophosphate.

In one embodiment, the RSA consists essentially of a material which, when exposed to radiation, softens, or becomes more soluble, swellable, or dispersible in a liquid medium, or becomes more tacky or absorbable. In one embodiment, the reactive material is a phenolic resin and the radiation-sensitive material is a diazonaphthoquinone.

Other radiation-sensitive systems that are known in the art can be used as well.

In one embodiment, the RSA comprises a fluorinated material. In one embodiment, the RSA comprises an unsaturated material having one or more fluoroalkyl groups. In one embodiment, the fluoroalkyl groups have from 2-20 carbon atoms. In one embodiment, the RSA is a fluorinated acrylate, a fluorinated ester, or a fluorinated olefin monomer. Examples of commercially available materials which can be used as RSA materials, include, but are not limited to, Zonyl® 8857A, a fluorinated unsaturated ester monomer available from E. I. du Pont de Nemours and Company (Wilmington, DE), and 3,3,4,4,5,5,6,6,7,7,8,8,9,9,10,10,11,11,12,12,12-eneicosafluorododecyl acrylate (H₂C═CHCO₂CH₂CH₂(CF₂)₉CF₃) available from Sigma-Aldrich Co. (St. Louis, Mo.).

In one embodiment, the RSA is a fluorinated macromonomer. As used herein, the term “macromonomer” refers to an oligomeric material having one or more reactive groups which are terminal or pendant from the chain. In some embodiments, the macromonomer has a molecular weight greater than 1000; in some embodiments, greater than 2000; in some embodiments, greater than 5000. In some embodiments, the backbone of the macromonomer includes ether segments and perfluoroether segments. In some embodiments, the backbone of the macromonomer includes alkyl segments and perfluoroalkyl segments. In some embodiments, the backbone of the macromonomer includes partially fluorinated alkyl or partially fluorinated ether segments. In some embodiments, the macromonomer has one or two terminal polymerizable or crosslinkable groups.

In one embodiment, the RSA is an oligomeric or polymeric material having cleavable side chains, where the material with the side chains forms films with a different surface energy that the material without the side chains. In one embodiment, the RSA has a non-fluorinated backbone and partially fluorinated or fully fluorinated side chains. The RSA with the side chains will form films with a lower surface energy than films made from the RSA without the side chains. Thus, the RSA can be can be applied to a first layer, exposed to radiation in a pattern to cleave the side chains, and developed to remove the side chains. This results in a pattern of higher surface energy in the areas exposed to radiation where the side chains have been removed, and lower surface energy in the unexposed areas where the side chains remain. In some embodiments, the side chains are thermally fugitive and are cleaved by heating, as with an infrared laser. In this case, development may be coincidental with exposure in infrared radiation. Alternatively, development may be accomplished by the application of a vacuum or treatment with solvent. In some embodiment, the side chains are cleavable by exposure to UV radiation. As with the infrared system above, development may be coincidental with exposure to radiation, or accomplished by the application of a vacuum or treatment with solvent.

In one embodiment, the RSA comprises a material having a reactive group and second-type functional group. The second-type functional groups can be present to modify the physical processing properties or the photophysical properties of the RSA. Examples of groups which modify the processing properties include plasticizing groups, such as alkylene oxide groups. Examples of groups which modify the photophysical properties include charge transport groups, such as carbazole, triarylamino, or oxadiazole groups.

In one embodiment, the RSA reacts with the underlying area when exposed to radiation. The exact mechanism of this reaction will depend on the materials used. After exposure to radiation, the RSA is removed in the unexposed areas by a suitable development treatment. In some embodiments, the RSA is removed only in the unexposed areas. In some embodiments, the RSA is partially removed in the exposed areas as well, leaving a thinner layer in those areas. In some embodiments, the RSA that remains in the exposed areas is less than 50Å in thickness. In some embodiments, the RSA that remains in the exposed areas is essentially a monolayer in thickness.

In one embodiment, a first layer is formed, the first layer is treated with an RSA, the treated first layer is exposed to radiation, and a second layer is formed over the treated and exposed first layer.

In one embodiment, the first layer is a substrate. The substrate can be inorganic or organic. Examples of substrates include, but are not limited to glasses, ceramics, and polymeric films, such as polyester and polyimide films.

In one embodiment, the first layer is deposited on a substrate. The first layer can be patterned or unpatterned. In one embodiment, the first layer is an organic active layer in an electronic device.

The first layer can be formed by any deposition technique, including vapor deposition techniques, liquid deposition techniques, and thermal transfer techniques. In one embodiment, the first layer is deposited by a liquid deposition technique, followed by drying. In this case, a first material is dissolved or dispersed in a liquid medium. The liquid deposition method may be continuous or discontinuous. Continuous liquid deposition techniques, include but are not limited to, spin coating, roll coating, curtain coating, dip coating, slot-die coating, spray coating, and continuous nozzle coating. Discontinuous liquid deposition techniques include, but are not limited to, ink jet printing, gravure printing, flexographic printing and screen printing. In one embodiment, the first layer is deposited by a continuous liquid deposition technique. The drying step can take place at room temperature or at elevated temperatures, so long as the first material and any underlying materials are not damaged.

The first layer is treated with an RSA. The treatment can be coincidental with or subsequent to the formation of the first layer.

In one embodiment, the RSA treatment is coincidental with the formation of the first organic active layer. In one embodiment, the RSA is added to the liquid composition used to form the first layer. When the deposited composition is dried to form a film, the RSA migrates to the air interface, i.e., the top surface, of the first layer in order to reduce the surface energy of the system.

In one embodiment, the RSA treatment is subsequent to the formation of the first layer. In one embodiment, the RSA is applied as a separate layer overlying, and in direct contact with, the first layer.

In one embodiment, the RSA is applied without adding it to a solvent. In one embodiment, the RSA is applied by vapor deposition. In one embodiment, the RSA is a liquid at room temperature and is applied by liquid deposition over the first layer. The liquid RSA may be film-forming or it may be absorbed or adsorbed onto the surface of the first layer. In one embodiment, the liquid RSA is cooled to a temperature below its melting point in order to form a second layer over the first layer. In one embodiment, the RSA is not a liquid at room temperature and is heated to a temperature above its melting point, deposited on the first layer, and cooled to room temperature to form a second layer over the first layer. For the liquid deposition, any of the methods described above may be used.

In one embodiment, the RSA is deposited from a second liquid composition. The liquid deposition method can be continuous or discontinuous, as described above. In one embodiment, the RSA liquid composition is deposited using a continuous liquid deposition method. The choice of liquid medium for depositing the RSA will depend on the exact nature of the RSA material itself. In one embodiment, the RSA is a fluorinated material and the liquid medium is a fluorinated liquid. Examples of fluorinated liquids include, but are not limited to, perfluorooctane, trifluorotoluene, and hexafluoroxylene. In a specific embodiment, the RSA is deposited using a continuous dispense nozzle to form a pattern of the RSA between pixels in a full-color display. The pattern may be in the form of lines that will, after exposure and a change in surface energy, prevent subsequently deposited liquid compositions from overflowing into neighboring pixels.

After the RSA treatment, the treated first layer is exposed to radiation. The type of radiation used will depend upon the sensitivity of the RSA as discussed above. The exposure can be a blanket, overall exposure, or the exposure can be patternwise. As used herein, the term “patternwise” indicates that only selected portions of a material or layer are exposed. Patternwise exposure can be achieved using any known imaging technique. In one embodiment, the pattern is achieved by exposing through a mask. In one embodiment, the pattern is achieved by exposing only select portions with a laser. The time of exposure can range from seconds to minutes, depending upon the specific chemistry of the RSA used. When lasers are used, much shorter exposure times are used for each individual area, depending upon the power of the laser. The exposure step can be carried out in air or in an inert atmosphere, depending upon the sensitivity of the materials.

In one embodiment, the radiation is selected from the group consisting of ultra-violet radiation (10-390 nm), visible radiation (390-770 nm), infrared radiation (770-10⁶ nm), and combinations thereof, including simultaneous and serial treatments. In one embodiment, the radiation is thermal radiation. In one embodiment, the exposure to radiation is carried out by heating. The temperature and duration for the heating step is such that at least one physical property of the RSA is changed, without damaging any underlying layers. In one embodiment, the heating temperature is less than 250° C. In one embodiment, the heating temperature is less than 150° C.

In one embodiment, the radiation is ultraviolet or visible radiation. In one embodiment, the radiation is applied patternwise, resulting in exposed regions of RSA and unexposed regions of RSA.

In one embodiment, after patternwise exposure to radiation, the first layer is treated to remove either the exposed or unexposed regions of the RSA. Patternwise exposure to radiation and treatment to remove exposed or unexposed regions is well known in the art of photoresists.

In one embodiment, the exposure of the RSA to radiation results in a change in the solubility or dispersibility of the RSA in solvents. When the exposure is carried out patternwise, this can be followed by a wet development treatment. The treatment usually involves washing with a solvent which dissolves, disperses or lifts off one type of area. In one embodiment, the patternwise exposure to radiation results in insolubilization of the exposed areas of the RSA, and treatment with solvent results in removal of the unexposed areas of the RSA.

In one embodiment, the exposure of the RSA to visible or UV radiation results in a reaction which decreases the volatility of the RSA in exposed areas. When the exposure is carried out patternwise, this can be followed by a thermal development treatment. The treatment involves heating to a temperature above the volatilization or sublimation temperature of the unexposed material and below the temperature at which the material is thermally reactive. For example, for a polymerizable monomer, the material would be heated at a temperature above the sublimation temperature and below the thermal polymerization temperature. It will be understood that RSA materials which have a temperature of thermal reactivity that is close to or below the volatilization temperature, may not be able to be developed in this manner.

In one embodiment, the exposure of the RSA to radiation results in a change in the temperature at which the material melts, softens or flows. When the exposure is carried out patternwise, this can be followed by a dry development treatment. A dry development treatment can include contacting an outermost surface of the element with an absorbent surface to absorb or wick away the softer portions. This dry development can be carried out at an elevated temperature, so long as it does not further affect the properties of the originally unexposed areas.

After treatment with the RSA, and exposure to radiation, the first layer has a lower surface energy than prior to treatment. In the case where part of the RSA is removed after exposure to radiation, the areas of the first layer that are covered by the RSA will have a lower surface energy that the areas that are not covered by the RSA.

The second layer is then applied over the RSA-treated first layer. The second layer can be applied by any deposition technique. In one embodiment, the second layer is applied by a liquid deposition technique. In this case, a liquid composition comprises a second material dissolved or dispersed in a liquid medium, applied over the RSA-treated first layer, and dried to form the second layer. The liquid composition is chosen to have a surface energy that is greater than the surface energy of the RSA-treated first layer, but approximately the same as or less than the surface energy of the untreated first layer. Thus, the liquid composition will wet the untreated first layer, but not spread onto the RSA-treated areas.

In one embodiment, the RSA is patterned and the second layer is applied using a continuous liquid deposition technique. In one embodiment, the second layer is applied using a discontinuous liquid deposition technique.

In one embodiment, the RSA is unpatterned and the second layer is applied using a discontinuous liquid deposition technique.

In one embodiment, the first layer is applied over a liquid containment structure. It may be desired to use a structure that is inadequate for complete containment, but that still allows adjustment of thickness uniformity of the printed layer. In this case it may be desirable to control wetting onto the thickness-tuning structure, providing both containment and uniformity. It is then desirable to be able to modulate the contact angle of the emissive ink. Most surface treatments used for containment (e.g., CF₄ plasma) do not provide this level of control.

In one embodiment, the first layer is applied over at least a portion of a well structure. Well structures are typically formed from photoresists, organic materials (e.g., polyimides), or inorganic materials (oxides, nitrides, and the like). Well structures may be used for containing the first layer in its liquid form, preventing color mixing; and/or for improving the thickness uniformity of the first layer as it is dried from its liquid form; and/or for protecting underlying features from contact by the liquid. Such underlying features can include conductive traces, gaps between conductive traces, thin film transistors, electrodes, and the like. It is often desirable to form regions on the well structures possessing different surface energies to achieve two or more purposes (e.g., preventing color mixing and also improving thickness uniformity). One approach is to provide a well structure with multiple layers, each layer having a different surface energy. A more cost effective way to achieve this modulation of surface energy is to control surface energy via modulation of the radiation used to cure a RSA. This modulation of curing radiation can be in the form of energy dosage (power * exposure time), or by exposing the RSA through a photomask pattern that simulates a different surface energy (e.g., expose through a half-tone density mask). The RSA layer may cover at least a portion of the top surfaces of the well structure, at least a portion of the side surfaces of the well structure, or a combination thereof.

In one embodiment of the process provided herein, the first and second layers are organic active layers. The first organic active layer is formed over a first electrode, the first organic active layer is treated with a reactive surface-active composition to reduce the surface energy of the layer, and the second organic active layer is formed over the treated first organic active layer.

In one embodiment, the first organic active layer is formed by liquid deposition of a liquid composition comprising the first organic active material and a liquid medium. The liquid composition is deposited over the first-electrode, and then dried to form a layer. In one embodiment, the first organic active layer is formed by a continuous liquid deposition method. Such methods may result in higher yields and lower equipment costs.

In one embodiment, the RSA treatment is subsequent to the formation of the first organic active layer. In one embodiment, the RSA is is applied as a separate layer overlying, and in direct contact with, the first organic active layer. In one embodiment, the RSA is deposited from a second liquid composition. The liquid deposition method can be continuous or discontinuous, as described above. In one embodiment, the RSA liquid composition is deposited using a continuous liquid deposition method.

The thickness of the RSA layer can depend upon the ultimate end use of the material. In some embodiments, the RSA layer is at least 100Å in thickness. In some embodiments, the RSA layer is in the range of 100Å-3000Å; in some embodiments 1000-2000Å.

After the RSA treatment, the treated first organic active layer is exposed to radiation. The type of radiation used will depend upon the sensitivity of the RSA as discussed above. The exposure can be a blanket, overall exposure, or the exposure can be patternwise.

In one embodiment, the exposure of the RSA to radiation results in a change in solubility or dispersibility of the RSA in a liquid medium. In one embodiment, the exposure is carried out patternwise. This can be followed by treating the RSA with a liquid medium, to remove either the exposed or unexposed portions of the RSA. In one embodiment, the RSA is radiation-hardenable and the unexposed portions are removed by the liquid medium.

The process described in this exemplary embodiment can be used for any successive pairs of organic layers in a device, where the second layer is to be contained in a specific area. As illustrated in FIG. 11, a device can be constructed with a first electrode 444 overlying the pixel circuitry. In one embodiment, when optional layer 790 is present, the RSA treatment can be applied to optional layer 790 to form patterned RSA layer 1102 prior to forming organic layer 1110. From a plan view, patterned RSA layer 1102 can be in the form of rows or columns of parallel lines, or combinations thereof. Patterned RSA layer 1102 can be formed between every row or column of pixels, between only select rows or columns of pixels, or a combination thereof. The widths and thicknesses of features of patterned RSA layer 1102 can be selected to best suit the processes being used-to-form-subsequent device layers. Skilled artisans will appreciate that an infinite number of patterns can be selected for patterned RSA layer 1102, and are too numerous to list. When optional layer 790 is not present, the RSA treatment can be applied to layer 570.

In another alternative embodiment, the edge portion of the organic layer may be thinner than the center portion rather than thicker than the center portion. The thinner edge portion can overlie portions of pixel driving circuits of a pixel and pixel driving circuits of surrounding pixels.

Other electronic devices may be formed in a similar manner. For example, the concepts described herein may be used to form passive matrix displays, active matrix displays, sensor arrays, or photovoltaic cells. In addition, concepts may be extended in the formation of other electronic components in which a layer is printed and lateral spreading of that printed material is a concern.

In further alternative embodiments, cathodes, anodes, and voltages may be switched. Devices described herein may be formed as top-emitting or bottom-emitting electronic devices.

5. Advantages

The electronic devices resulting from the processes described herein can be free of well structures. Such processes reduce the processing time and reduce costs associated with forming such electronic components. In some embodiments, the processes described herein can be used in conjunction with well structures to provide improved containment of deposited liquids.

The thickness of the organic layer in the center portion over the underlying electrode is relatively uniform and the useful and effective surface area for emitting radiation is improved (with or without well structures). In addition, the edge portions of the organic layers overlie transistors and other pixel driving circuit components that may be sensitive to electromagnetic radiation, reducing the exposure of such components to electromagnetic radiation. Additionally, edge portions of the organic layers that extend beyond the dimensions of the underlying first electrodes can prevent leakage currents or short-circuiting of charges near the edges of the first electrodes that can diminish device performance.

The modifications to existing equipment and processes are relatively straightforward. Integration of the processes into an existing process flow does not require radical changes to process flows.

Note that not all of the activities described above in the general description or the examples are required, that a portion of a specific activity may not be required, and that further activities may be performed in addition to those described. Still further, the order in which each of the activities are listed are not necessarily the order in which they are performed. After reading this specification, skilled artisans will be capable of determining what activities can be used for their specific needs or desires.

In the foregoing specification, the invention has been described with reference to specific embodiments. However, one of ordinary skill in the art appreciates that various modifications and changes can be made without departing from the scope of the invention as set forth in the claims below. Accordingly, the specification and figures are to be regarded in an illustrative rather than a restrictive sense and all such modifications are intended to be included within the scope of invention.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as a critical, required, or essential feature or element of any or all the claims.

It is to be appreciated that certain features of the invention which are, for clarity, described above and below in the context of separate embodiments, may also be provided in combination in a single embodiment. Conversely, various features of the invention that are, for brevity, described in the context of a single embodiment, may also be provided separately or in any subcombination. Further, reference to values stated in ranges includes each and every value within that range.

What is claimed is:

1. An electronic device comprising:
a substrate;
a first layer;
a first pixel comprising:
a first pixel driving circuit that overlies the substrate; and
a first electronic component comprising a first electrode and a second layer, wherein:
the first electrode overlies at least part of the first pixel driving circuit; and
within the first pixel:
the second layer overlies the first electrode and the first layer;
the second layer comprises a central portion and an edge portion;
the edge portion of the second layer has a significantly different thickness than the central portion of the second layer; and
from a plan view, at least a part of the edge portion of the second layer overlies at least part of the first pixel driving circuit; and
a patterned reactive surface-active layer, wherein the patterned reactive surface-active layer has a lower surface energy than the first layer.

2. The electronic device of claim 1., wherein the second layer is selected from a group consisting of an organic active layer, a charge transport layer, a charge blocking layer, a charge injection layer and combinations thereof.

3. The electronic device of claim 1, wherein the patterned reactive surface-active layer comprises a fluorinated material.

4. The electronic device of claim 1, wherein the patterned reactive surface-active layer comprises a crosslinkable material.

5. The electronic device of claim 1-, wherein the first layer is selected from a group consisting of a charge transport layer, a charge blocking layer, a charge injection layer, and combinations thereof.

6. The electronic device of claim 1, further comprising a second electrode, wherein:
the second layer is a first organic active layer; and
the second electrode overlies the first organic active layer.

7. The electronic device of claim 6, wherein the electronic device is an organic electronic device.

8. The electronic device of claim 1, further comprising a second pixel comprising:
a second pixel driving circuit that overlies the substrate; and
a second electronic component comprising a first electrode and a third layer, wherein:
the second layer is a first organic active layer having a composition different from the third layer;
the first electrode of the second electronic component overlies at least part of the second pixel driving circuit; and
within the second pixel:
the third layer overlies the first layer and the first electrode of the second electronic component;
the third layer comprises a central portion and an edge portion;
the edge portion of the third layer has a significantly different thickness than the central portion of the third layer; and
from a plan view, at least a part of the edge portion of the third layer overlies at least part of the second pixel driving circuit.

9. The electronic device of claim 8, wherein from a plan view the second layer and the third layer are spaced apart from each other by a barrier region.

10. The electronic device of claim 9, wherein the barrier region comprises the patterned reactive surface-active layer.

11. The electronic device of claim 10, wherein the barrier region further comprises a well structure, wherein the patterned reactive surface-active layer overlies the well structure.

12. A process for forming an electronic device comprising:
forming a first pixel driving circuit over a substrate;
forming a first electrode of a first electronic component over the substrate, wherein the first electrode overlies at least part of the first pixel driving circuit;
forming a first layer;
forming a patterned reactive surface-active layer, wherein the patterned reactive surface-active layer has a lower surface energy than the first layer; and
forming a second layer over the first electrode of the first electronic component, wherein:
the second layer comprises a central portion and an edge portion;
the edge portion of the second layer has a significantly different thickness than the central portion of the second layer; and
from a plan view, at least a part of the edge portion of the second layer overlies at least part of the first pixel driving circuit.

13. The process of claim 12, wherein the second layer is selected from a group consisting of an organic active layer, a charge transport layer, a charge blocking layer, a charge injection layer and combinations thereof.

14. The process of claim 12, wherein the patterned reactive surface-active layer comprises a fluorinated material.

15. The process of claim 12, wherein the patterned reactive surface-active layer comprises a crosslinkable material.

16. The process of claim 12, wherein the first layer is selected from a group consisting of a charge transport layer, a charge blocking layer, a charge injection layer, and combinations thereof.

17. The process of claim 12, wherein:
the second layer is a first organic active layer; and
the process further comprises forming a second electrode over the first organic active layer.

18. The process of claim 17, wherein the electronic device is an organic electronic device.

19. The process of claim 12, wherein:
forming a first pixel driving circuit comprises forming a second pixel driving circuit over the substrate; and
forming the first electrode comprises forming a first electrode of a second electronic component over the substrate, wherein the first electrode overlies at least part of the second pixel driving circuit;
the process further comprises forming a third layer over the first electrode of the second electronic component, wherein:
the second layer is a first organic active layer having a composition different from the third layer;
the third layer comprises a central portion and an edge portion;
the edge portion of the third layer is significantly thicker than the central portion of the third layer; and
from a plan view, at least a part of the edge portion of the third layer overlies at least part of the second pixel driving circuit.

20. The process of claim 19, wherein from a plan view the second layer and the third layer are spaced apart from each other by a barrier region.

21. The process of claim 20, wherein the barrier region comprises the patterned reactive surface-active layer.
